(19) United States
(12) Patent Application Publication
(10) Pub. No.: US 2025/0265702 A1
(43) Pub. Date: Aug. 21, 2025

(54) MEASUREMENT POSITION MONITORING APPARATUS AND SEMICONDUCTOR MANUFACTURING EQUIPMENT INCLUDING THE SAME

(71) Applicant: SAMSUNG ELECTRONICS CO., LTD., Suwon-si (KR)

(72) Inventors: Seok Ho KIM, Suwon-si (KR); Woo-Jin HAN, Suwon-si (KR)

(73) Assignee: SAMSUNG ELECTRONICS CO., LTD., Suwon-si (KR)

(21) Appl. No.: 18/898,075

(22) Filed: Sep. 26, 2024

(30) Foreign Application Priority Data
Feb. 15, 2024 (KR) 10-2024-0021580

(51) Int. Cl. G06T 7/00; G06V 10/75; G06V 10/98; H01L 21/68

(52) U.S. Cl. CPC G06T 7/001; G06V 10/751; G06V 10/98; H01L 21/681; G06T 2207/30148

(57) ABSTRACT

A measurement position monitoring apparatus and a method of operating the same are provided. The method of operating the measurement position monitoring apparatus may include extracting a pattern from an image associated with a substrate, wherein the pattern is a bounded pattern; calculating a position of a target point within the extracted pattern; comparing the target point with a reference point; and calculating a position error in the target point.

### CROSS-REFERENCE TO RELATED APPLICATION

This application claims priority from Korean Patent Application No. 10-2024-0021580 filed on Feb. 15, 2024, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a measurement position monitoring apparatus that is applicable to a semiconductor manufacturing process and semiconductor manufacturing equipment that includes the measurement position monitoring apparatus.

### 2. Description of the Related Art

When inspecting patterns on a substrate, it is possible to detect each desired part on the substrate using an align key after aligning the edges of the substrate. Recently, semiconductors have been miniaturized, and patterns have become ultrafine. In such an environment, the aforementioned inspection method has limitations in considering the minute misalignment of a stage supporting a substrate or patterns within the substrate.

### SUMMARY

Aspects of the present disclosure provide a measurement position monitoring apparatus and a method of operating the same. Aspects of the present disclosure also provide semiconductor manufacturing equipment including the measurement position monitoring apparatus.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a measurement position monitoring apparatus includes: a pattern extraction unit extracting a pattern from an image associated with a substrate, wherein the pattern is a bounded pattern; a calculation unit calculating a position of a target point within the extracted pattern; a comparison unit comparing the target point with a reference point; and a position error calculation unit calculating a position error in the target point.

According to another aspect of the present disclosure, semiconductor manufacturing equipment includes: a stage supporting a substrate; a substrate inspection unit inspecting the substrate; and a measurement position monitoring apparatus monitoring a position of a target point within the substrate. The measurement position monitoring apparatus includes a memory storing one or more instructions; and at least one processor configured to execute the one or more instructions. The one or more instructions, when executed by the at least one processor, cause the measurement position monitoring apparatus to extract a pattern from an image associated with the substrate, wherein the pattern is a bounded pattern, calculate the position of the target point within the extracted pattern, compare the target point with a reference point, and calculate a position error in the target point.

According to another aspect of the present disclosure, a method for monitoring position monitoring includes extracting a pattern from an image associated with a substrate, wherein the pattern is a bounded pattern; calculating a position of a target point within the extracted pattern; comparing the target point with a reference point; and calculating a position error in the target point. Wherein, the extracted pattern is formed within a scribe lane between a plurality of cells and is associated with an oxide site (OS) box; the target point is the target point is an inner center of the extracted pattern, the reference point is associated with a field of view (FOV) of an image acquisition unit that has acquired the image, the position error includes a first component in a first direction and a second component in a second direction that is perpendicular to the first direction, and calculating the position error includes calculating a distance between the target point and the reference point based on pixels within the image and calculates the position error based on the distance.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail exemplary embodiments thereof with reference to the attached drawings, in which:

FIG. 1 is a first exemplary block diagram illustrating the internal configuration of a measurement position monitoring apparatus according to some embodiments of the present disclosure.

FIG. 2 is an exemplary schematic diagram illustrating pattern extraction according to some embodiments of the present disclosure.

FIG. 3 is an exemplary schematic diagram illustrating pattern extraction according to some embodiments of the present disclosure.

FIG. 4 is a schematic diagram illustrating a position for a target point according to some embodiments of the present disclosure.

FIG. 5 is an exemplary schematic diagram illustrating position error according to some embodiments of the present disclosure.

FIG. 6 is an exemplary schematic diagram illustrating position error calculation according to some embodiments of the present disclosure.

FIG. 7 is a flowchart illustrating an error calculation method for calculating the position error, according to an embodiment of the present disclosure.

FIG. 8 is a flowchart for explaining illustrating a method of error calculation according to another embodiment of the present disclosure.

FIG. 9 is an exemplary block diagram illustrating the internal configuration of the measurement position monitoring apparatus according to some embodiments of the present disclosure.

FIG. 10 is an exemplary schematic diagram illustrating the internal configuration of the measurement position monitoring apparatus according to some embodiments of the present disclosure.

FIG. 11 is an exemplary diagram illustrating semiconductor manufacturing according to some embodiments of the present disclosure.

FIG. 12 is an exemplary diagram illustrating semiconductor manufacturing according to some embodiments of the present disclosure.

FIG. 13 is an exemplary diagram illustrating semiconductor manufacturing according to some embodiments of the present disclosure.

### DETAILED DESCRIPTION

Embodiments of the present disclosure will hereinafter be described with reference to the accompanying drawings. The same reference numerals are used for identical components in the drawings, and redundant explanations for these components are omitted.

The present disclosure relates to a measurement position monitoring apparatus that can be applied to a semiconductor manufacturing process such as substrate processing. The present disclosure also relates to an inspection process and semiconductor manufacturing equipment that includes the measurement position monitoring apparatus. The measurement position monitoring apparatus may calculate an error in a measurement position based on the results of comparison of the center of a pattern (e.g., closed pattern) and the center of a field of view (FOV).

In the present disclosure, first and second directions D1 and D2 form a horizontal two-dimensional (2D) plane. For example, the first direction D1 may be a front-back direction, and the second direction D2 may be a left-right direction. Alternatively, the first direction D1 may be the left-right direction, and the second direction D2 may be the front-back direction. A third direction D3 forms a three-dimensional (3D) space together with the first and second directions D1 and D2. The third direction D3 is perpendicular to the plane formed by the first and second directions D1 and D2. The third direction D3 may be an up-down direction.

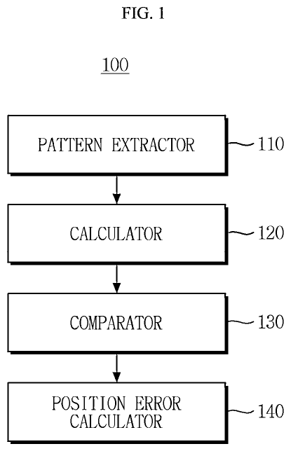

FIG. 1 is a first exemplary block diagram illustrating the internal configuration of a measurement position monitoring apparatus according to some embodiments of the present disclosure. Referring to FIG. 1, a measurement position monitoring apparatus 100 may include a pattern extractor 110, a calculator 120, a comparator 130, and a position error calculator 140.

The pattern extractor 110 may extract a pattern from an image. The image may be an image associated with a substrate. The substrate may be a wafer. In embodiments, the substrate may be a reticle. The substrate may be understood as encompassing a wafer, a reticle, etc., for use in the production of a semiconductor product. The extracted pattern may be a closed pattern or a bounded pattern. That is, the extracted pattern may be a pattern with its inside defined. For example, the extracted pattern may be a polygon, such as a rectangle or a pentagon. Alternatively, the extracted pattern may be a circle or an ellipse. The extracted pattern may be formed in a dummy area. For example, the extracted pattern may be formed in a scribe lane between multiple cell areas on the substrate. The extracted pattern may also be an oxide site (OS) box.

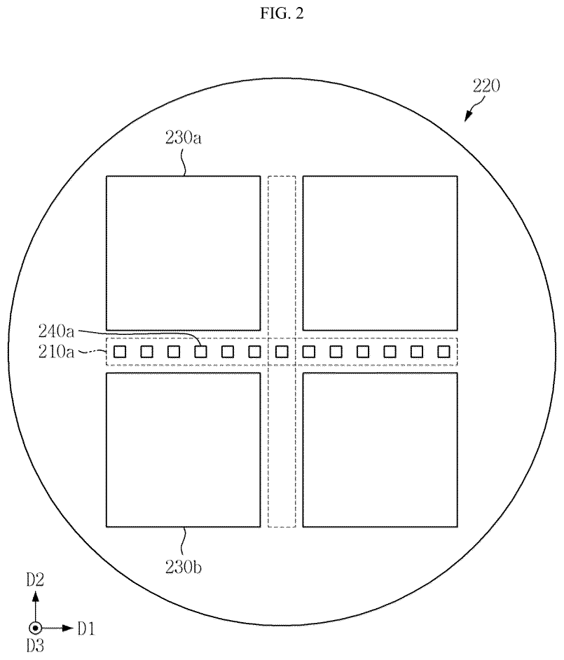

FIG. 2 is an exemplary schematic diagram for explaining the pattern extractor of the measurement position monitoring apparatus according to some embodiments of the present disclosure.

Referring to FIG. 2, a first scribe lane 210a may be formed between a first cell 230a and a second cell 230b within a substrate 220. The pattern extractor 110 may extract an OS box formed within the first scribe lane 210a as a pattern. A plurality of OS boxes may be formed within the first scribe lane 210a. The pattern extractor 110 may extract one of the OS boxes 240a formed within the first scribe lane 210a as a pattern.

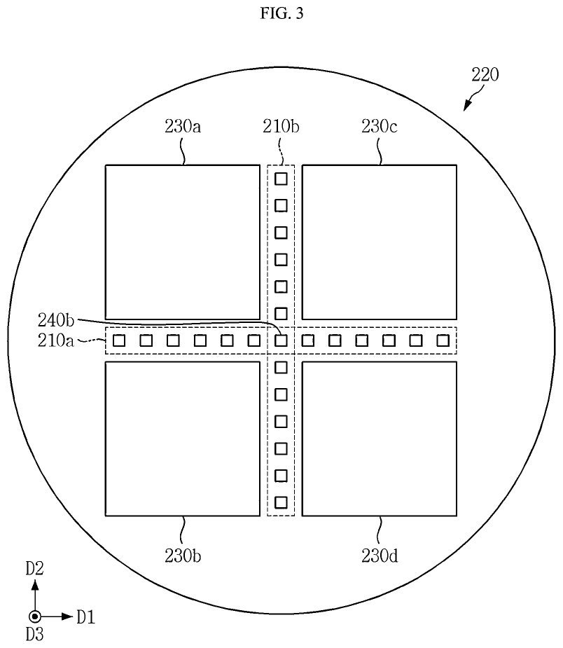

FIG. 3 is an exemplary schematic diagram for explaining the pattern extractor of the measurement position monitoring apparatus according to some embodiments of the present disclosure.

Referring to FIG. 3, a first scribe lane 210a may be formed having the first direction D1 as its length direction. The first scribe lane 210a may be formed between a first cell 230a and a second cell 230b within the substrate 220. The first scribe lane 210a may also be formed between a third cell 230c and a fourth cell 230d within the substrate 220. The second scribe lane 210b may be formed having the second direction D2 as its length direction. The second scribe lane 210b may be formed between the first and third cells 230a and 230c within the substrate 220. The second scribe lane 210b may be formed between the second and fourth cells 230b and 230d within the substrate 220. The pattern extractor 110 may extract an OS box 240b formed at the intersection between the first and second scribe lanes 210a and 210b as a pattern.

The pattern extractor 110 may extract a pattern through image processing. The pattern extractor 110 may extract a pattern from the image via processes such as image preprocessing, binarization, boundary extraction, the setting of a region of interest, and pattern detection.

Referring back to FIG. 1, the calculator 120 may calculate the position of a target point within the extracted pattern. The target point may be the inner center of the extracted pattern. The calculator 120 may calculate the position of the inner center of the extracted pattern. As previously described, the extracted pattern may be a closed pattern.

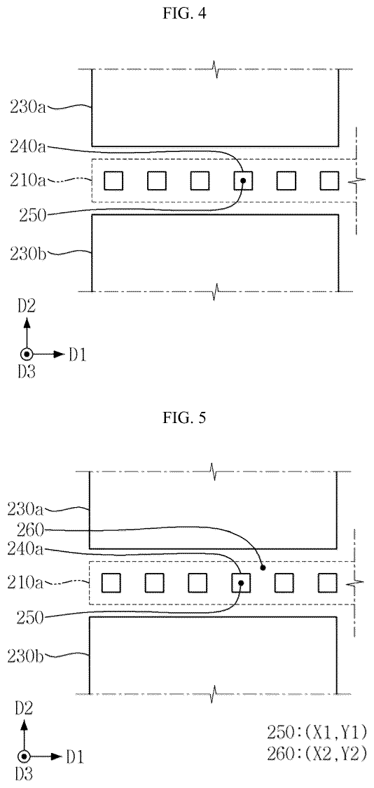

Referring to FIG. 4, a point within an OS box 240a, for example the inner center 250, where the distance to each vertex of the OS box 240a is identical may be detected. The calculator 120 may calculate the point as the inner center of the extracted pattern. FIG. 4 is a schematic diagram for explaining the calculator of the measurement position monitoring apparatus according to some embodiments of the present disclosure.

Referring again to FIG. 1, the comparator 130 may compare the inner center of the extracted pattern with a reference point. Information on the reference point may be stored in advance. In embodiments, the information on the reference point may be stored in a memory within the measurement position monitoring apparatus 100. In embodiments, the information on the reference point may be received from an external device. In embodiments, the information on the reference point may be provided by a camera sensor.

In embodiments, the pattern extractor 110 may extract a pattern from the image. The information on the reference point may be information on the camera sensor that has acquired the image. For example, the reference point may be the center of a field-of-view (FOV). The reference point may be the center of the FOV of the camera sensor that has acquired the image.

The position error calculator 140 may calculate a position error in the target point. The position error may be a measurement position error in the camera sensor. The position error calculator 140 may calculate the position error in the target point based on the error between the target point and the reference point. The position error calculator 140 may calculate the position error in the target point as the error between the inner center of an OS box and the center of the FOV of the camera sensor. The target point may be represented by first planar coordinates consisting of X- and Y-axis coordinates. The reference point may be represented by second planar coordinates consisting of X- and Y-axis coordinates. The first planar coordinates and the second planar coordinates may be calculated in units of pixels within the image.

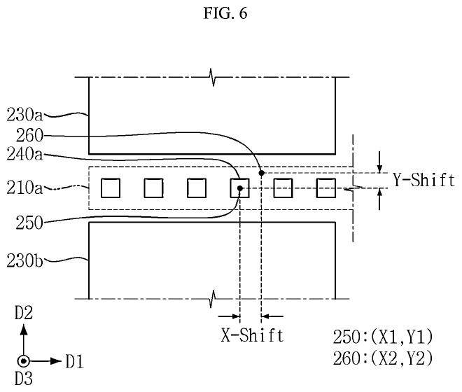

FIGS. 5 and 6 are exemplary schematic diagrams for explaining the position error calculator of the measurement position monitoring apparatus according to some embodiments of the present disclosure.

Referring to FIGS. 5 and 6, the inner center 250 of the OS box 240a may be represented by first planar coordinates (X1, Y1) where X1 and Y1 are first X- and Y-axis coordinate values, respectively, of the inner center 250 of the OS box 240a. The second planar coordinates of an FOV center 260 of the camera sensor may be represented as (X2, Y2) where X2 and Y2 are second X- and Y-axis coordinate values, respectively, of the FOV center 260. The position error calculator 140 may calculate a difference X-Shift between the first and second X-axis coordinate values X1 and X2 as error. The difference X-Shift may be X1-X2 or X2-X1. The position error calculator 140 may calculate a difference Y-Shift between the first and second Y-axis coordinate values Y1 and Y2 as error. The difference Y-Shift may be Y1-Y2 or Y2-Y1.

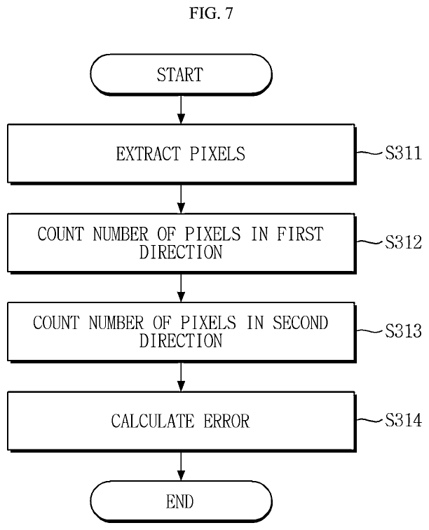

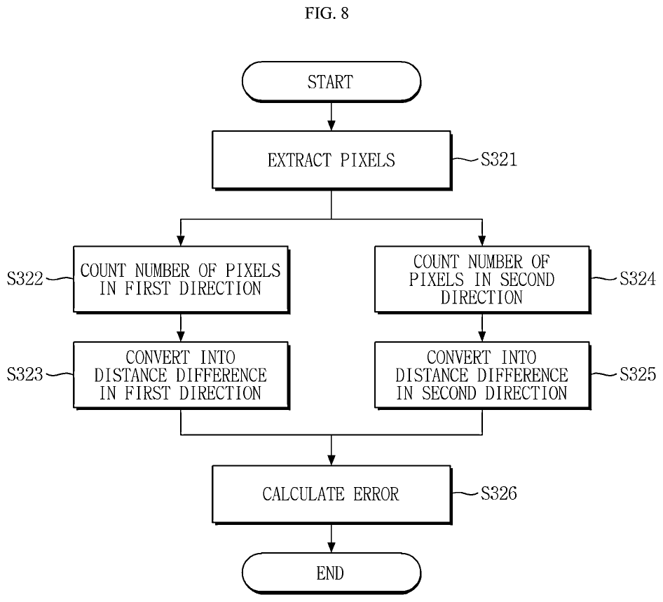

FIG. 7 is a flowchart for explaining steps of an error calculation method of the position error calculation unit, according to an embodiment of the present disclosure.

The position error calculator 140 may calculate the position error in the target point based on the number of pixels located between the inner center 250 of the OS box 240a and the FOV center 260 of the camera sensor. The image may consist of a plurality of pixels, and the inner center 250 and the FOV center 260 may each consist of a single pixel.

Referring to FIG. 7, At operation S311, the position error calculator 140 may extract pixels within the image that are located between the inner center 250 of the OS box 240a and the FOV center 260. At operation S312, the position error calculator 140 may count the number of pixels arranged in the first direction D1 between the inner center 250 of the OS box 240a and the FOV center 260 based on the extracted pixels. At operation S313, the position error calculator 140 may count the number of pixels arranged in the second direction D2 between the inner center 250 of the OS box 240a and the FOV center 260 based on the extracted pixels. Then, at operation S314, position error calculator 140 may calculate the position error in the target point based on the counted numbers of pixels.

In embodiments, operations S312 and S313 may be performed simultaneously, but the present disclosure is not limited thereto. In embodiments, operation S313 may be performed after operation S312. In a same or another embodiment, operation S313 may be performed prior to operation S312.

The position error calculator 140 may calculate the position error in the target point based on the distance between the inner center 250 of the OS box 240a and the FOV center 260. The size of pixels within the image may be uniform. In embodiments, the distance between pixels within the image may be uniform. The position error calculator 140 may define the size of pixels or the distance between pixels as, for example, k μm (where k is a positive rational number).

FIG. 8 is a flowchart for explaining the method of error calculation by the position error calculator according to another embodiment of the present disclosure.

Referring to FIG. 8, at operation S321, the position error calculator 140 may extract the pixels within the image that are located between the inner center 250 of the OS box 240a and the FOV center 260. At operation 322, position error calculator 140 may count the number of pixels arranged in the first direction D1 between the inner center 250 of the OS box 240a and the FOV center 260 based on the extracted pixels. Thereafter, at operation S323, the position error calculator 140 may convert the number of pixels arranged in the first direction D1 between the inner center 250 and the FOV center 260 into a distance difference.

In the same or another embodiment, at operation S324, the position error calculator 140 may count the number of pixels arranged in the second direction D2 between the inner center 250 of the OS box and the FOV center 260 based on the extracted pixels. Thereafter, at operation S325, the position error calculator 140 may convert the number of pixels arranged in the second direction D2 between the inner center 250 and the FOV center 260 into a distance difference. Operations S322 and S324 may be performed simultaneously, but the present disclosure is not limited thereto. In a same or another embodiment, operation S324 may be performed prior to operation S322.

At operation S326, the position error calculator 140 may calculate the position error in the target point based on the distance differences obtained in operations S323 and/or S325. For example, if the size of pixels or the distance between pixels is defined as 1 μm, and there are five pixels in the first direction D1 and three pixels in the second direction D2, then the position error calculator 140 may convert the distance difference in the first direction D1 to 5 μm and the distance difference in the second direction D2 to 3 μm. The position error calculator 140 may calculate the distance differences of 5 μm and 3 μm in the first and second directions D1 and D2 as the position error in the target point.

The measurement position monitoring apparatus 100 may include a processor that executes control over each of its components, one or more instructions related to functions or operations for controlling each of its components, a processing recipe that includes the instructions, a memory for storing various data, and a network for wired or wireless communication with an external device. The measurement position monitoring apparatus 100 may further include a user interface. The user interface may include an input module for an operator to perform a command input operation for managing the measurement position monitoring apparatus 100, and an output module for visualizing and displaying operational status, computation process and its results, and control status. The measurement position monitoring apparatus 100 may be provided as a computing device for data processing and analysis, and command transmission.

The instructions may be provided in the form of a computer program or application. The computer program may include one or more instructions and may be stored on a computer-readable storage medium. The instructions may include code generated by a compiler, code executable by an interpreter, etc. The memory may be provided as at least one storage medium selected from among a flash memory, a hard disk drive (HDD), a solid state drive (SSD), a card-type memory, a random-access memory (RAM), a static RAM (SRAM), a read-only memory (ROM), an electrically erasable programmable ROM (EEPROM), a programmable ROM (PROM), a magnetic memory, a magnetic disk, and an optical disk.

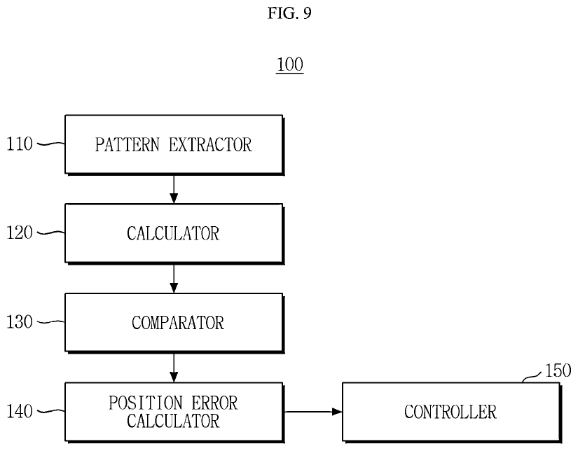

In some embodiments, the measurement position monitoring apparatus 100 may further include a controller 150. FIG. 9 is an exemplary block diagram illustrating the internal configuration of the measurement position monitoring apparatus according to some embodiments of the present disclosure. Referring to FIG. 9, the controller 150 may adjust the position of a control target based on the position error calculated by the position error calculator 140.

Referring to FIG. 9, the controller 150 may adjust the position of a stage supporting the substrate 220 based on the differences between the coordinates (X1, Y1) of the inner center 250 of the OS box 240a and the coordinates (X2, Y2) of the FOV center 260 of the camera sensor. The controller 150 may shift the stage in the first direction D1 by a first distance based on the differences between the first and second X-axis coordinate values X1 and X2, e.g., (X1-X2) or (X2-X1). Similarly, the controller 150 may shift the stage in the second direction D2 by a second distance based on the difference between the first and second Y-axis coordinate values, e.g., (Y1-Y2) or (Y2-Y1).

When calculating position error based on the number of pixels located between the inner center 250 and the FOV center 260, the position error calculator 140 may calculate the position error as the numbers of pixels arranged in the first and second directions D1 and D2 between the inner center 250 and the FOV center 260. The controller 150 may shift the stage in the first direction D1 by a first distance based on the number of pixels arranged in the first direction D1 between the inner center 250 and the FOV center 260, and may shift the stage in the second direction D2 by a second distance based on the number of pixels arranged in the second direction D2 between the inner center 250 and the FOV center 260.

When calculating the position error based on the distance between the inner center 250a and the FOV center 260, the position error calculator 140 may calculate the distance differences, in the first direction D1 and the second direction D2, between the inner center 250a and the FOV center 260 as the position error. The controller 150 may shift the stage in the first direction D1 by a first distance based on the calculated distance difference in the first direction D1, and may shift the stage in the second direction D2 by a second distance based on the calculated distance difference in the second direction D2.

The controller 150 may be provided as a computing device. The controller 150 may be provided as a single computing device together with the pattern extractor 110, the calculator 120, the comparator 130, and the position error calculator 140, but the present disclosure is not limited thereto. Alternatively, the controller 150 may be provided as a separate computing device from the pattern extractor 110, calculator 120, comparator 130, and position error calculator 140. In the former case, the measurement position monitoring apparatus 100 may be provided as a single computing device. In the latter case, the measurement position monitoring apparatus 100 may be provided as two computing devices.

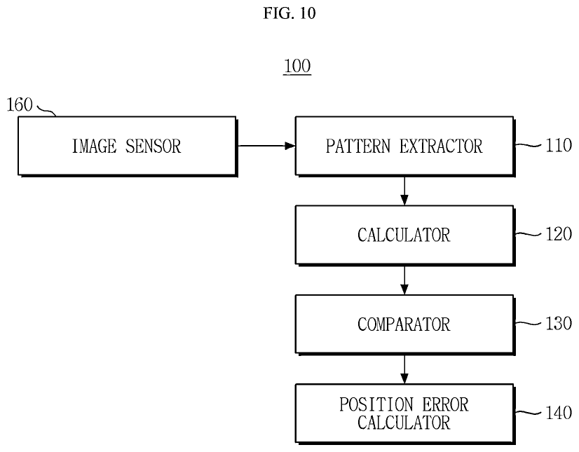

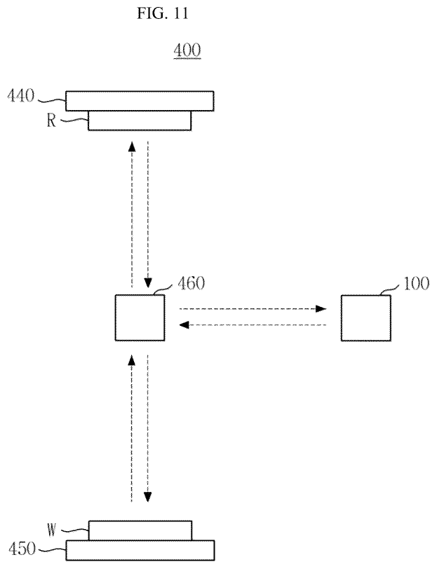

FIG. 10 is an exemplary schematic diagram illustrating the internal configuration of the measurement position monitoring apparatus according to some embodiments of the present disclosure.

In some embodiments, the measurement position monitoring apparatus 100 may further include an image sensor 160. Referring to FIG. 10, the image sensor 160 may acquire the image. The pattern extractor 110 may extract the extracted pattern from the image acquired by the image sensor 160. The image sensor 160 may be provided as a camera sensor.

Referring to FIG. 10, the image sensor 160 may acquire an image related to the substrate 220. For example, the image sensor 160 may acquire an image that includes a first OS box 240a. The image sensor 160 may acquire an image that includes the first OS box 240a and the first and second cells 230a and 230b, located on both sides of the first OS box 240a. Alternatively, the image sensor 160 may acquire an image that includes a second OS box 240b. The image sensor 160 may acquire an image that includes the second OS box 240b and the first, second, third, and fourth cells 230a, 230b, 230c, and 230d, located around the second OS box 240b.

The measurement position monitoring apparatus 100 may further include only the image sensor 160. Specifically, as illustrated in FIG. 10, the measurement position monitoring apparatus 100 may be configured to include the pattern extractor 110, the calculator 120, the comparator 130, the position error calculator 140, and the image sensor 160, but the present disclosure is not limited thereto. In embodiments, the measurement position monitoring apparatus 100 may further include not only the image sensor 160, but also the controller 150. That is, the measurement position monitoring apparatus 100 may be configured to include the pattern extractor 110, the calculator 120, the comparator 130, the position error calculator 140, the controller 150, and the image sensor 160.

The measurement position monitoring apparatus 100 may be applicable to a semiconductor manufacturing process. For example, the measurement position monitoring apparatus 100 may monitor a measurement position during an inspection process for the substrate 220. The measurement position monitoring apparatus 100 may monitor the measurement position when inspecting patterns on the substrate 220. Alternatively, the measurement position monitoring apparatus 100 may monitor the measurement position when inspecting materials (e.g., oxide films) formed on the substrate 220. Yet alternatively, the measurement position monitoring apparatus 100 may monitor the measurement position when comparing patterns between a reticle and a wafer.

The measurement position monitoring apparatus 100 may also be applicable to semiconductor manufacturing equipment. For example, the measurement position monitoring apparatus 100 may be provided within equipment performing a photolithography process. The measurement position monitoring apparatus 100 may monitor the measurement position before performing the photolithography process. The measurement position monitoring apparatus 100 may monitor the measurement position after completing the photolithography process.

The measurement position monitoring apparatus 100 may utilize a measurement image from the semiconductor manufacturing equipment to extract a target pattern to be measured, calculate the center of the extracted pattern, compare the calculated center with a reference value, and quantify and visualize the error in the measurement position based on the results of the comparison.

The measurement position monitoring apparatus 100 may extract one or more closed patterns. For example, the measurement position monitoring apparatus 100 may extract the first or second OS box 240a or 240b within the substrate 220. The measurement position monitoring apparatus 100 may extract the first or second OS box 240a or 240b using the differences in contrast between the pixels in the image.

The measurement position monitoring apparatus 100 may use the center of the FOV as the reference value. Each pixel in the image acquired through the FOV of the image sensor 160 may be converted to a distance value. The measurement position monitoring apparatus 100 may quantify and visualize the error in the measurement position by converting differences in the pixels in the image to distance values.

The measurement position monitoring apparatus 100 may detect a target measurement position through the image and may calculate the error between the detected target position and the actual measured position, thereby monitoring the accuracy of the position measurement device. The measurement position monitoring apparatus 100 may control a target associated with the measurement position based on the error in the measurement position. For example, the measurement position monitoring apparatus 100 may adjust the position of the stage supporting the substrate 220.

The measurement position monitoring apparatus 100 may inspect the patterns on the substrate 220. For example, the measurement position monitoring apparatus 100 may inspect the patterns on the substrate 220 by comparing a reticle and a wafer. FIG. 11 is a first exemplary diagram for explaining semiconductor manufacturing equipment including the measurement position monitoring apparatus according to some embodiments of the present disclosure.

Semiconductor manufacturing equipment 400 may be provided as a substrate inspection apparatus. Referring to FIG. 11, the semiconductor manufacturing equipment 400 may include a first stage 440, a second stage 450, a substrate inspection unit 460, and the measurement position monitoring apparatus 100.

A reticle R may be disposed on the first stage 440. A wafer W may be disposed on the second stage 450. The first and second stages 440 and 450 may move in one of the first, second, and third directions D1, D2, and D3. Alternatively, the first and second stages 440 and 450 may rotate in one of the first, second, and third directions D1, D2, and D3.

The substrate inspection unit 460 may inspect the wafer W. The substrate inspection unit 460 may inspect patterns formed on the wafer W. The substrate inspection unit 460 may inspect the patterns formed on the wafer W by comparing the reticle R and the wafer W.

The measurement position monitoring apparatus 100 may monitor a measurement position on the wafer W. The measurement position monitoring apparatus 100 may provide the measurement position on the wafer W to the substrate inspection unit 460. The substrate inspection unit 460 can accurately inspect a desired part of the wafer W based on information provided by the measurement position monitoring apparatus 100.

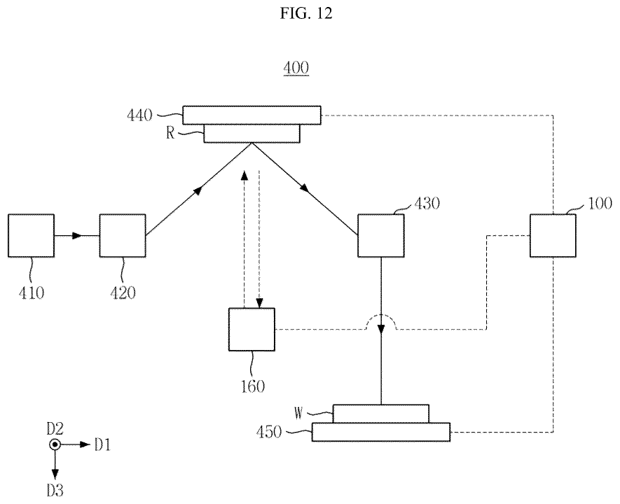

The semiconductor manufacturing equipment 400 may be provided as a substrate processing apparatus. The semiconductor manufacturing equipment 400 may be provided as a substrate processing apparatus that performs an exposure process using extreme ultraviolet (EUV) light. The substrate processing apparatus may be an exposure apparatus containing an EUV light source. FIG. 12 is a second exemplary diagram for explaining the semiconductor manufacturing equipment including the measurement position monitoring apparatus according to some embodiments of the present disclosure.

Referring to FIG. 12, the semiconductor manufacturing equipment 400 may be configured to include a light source 410, a first optical system 420, a second optical system 430, a first stage 440, a second stage 450, an image sensor 160, and a measurement position monitoring apparatus 100. The measurement position monitoring apparatus 100 may be an apparatus that includes a pattern extractor 110, a calculator 120, a comparator 130, a position error calculator 140, and a controller 150.

The light source 410 may generate and output EUV light with high energy density within a predetermined wavelength range. For example, the light source 410 may generate and output EUV light within a wavelength range of 5 nm to 50 nm. The light source 410 may be provided as a plasma-based light source. For example, the light source 410 may be provided as a laser produced plasma (LPP) light source or a discharge produced plasma (DPP) light source, but the present disclosure is not limited thereto. Alternatively, the light source 410 may be provided as a synchrotron radiation light source. If provided as a plasma-based light source, the light source 410 may include a focusing mirror such as an elliptical mirror or a spherical mirror to concentrate the EUV light. The focusing mirror can increase the energy density of light incident upon the first optical system 420.

The first optical system 420 may be provided as an illumination optics system. Alternatively, the first optical system 420 may be provided as a free-form optics system. The first optical system 420 may include a plurality of mirrors. The first optical system 420 may include field facet mirrors (FFMs) or pupil facet mirrors (PFMs).

The first optical system 420 may deliver the EUV light provided from the light source 410 to the reticle R. The EUV light may be sequentially reflected through the mirrors within the first optical system 420 and may then incident upon the surface of the reticle R. For example, the reticle R may be a photomask. The first optical system 420 may shape the EUV light into a curved slit form for incidence upon the reticle R. The curved slit form of the EUV light may represent a two-dimensional (2D) parabolic curve on an XY plane.

The second optical system 430 may be provided as a projection optics system. The second optical system 430, like the first optical system 420, may include a plurality of mirrors. The second optical system 430 may transmit EUV light reflected from the reticle R to the wafer W. The second optical system 430 may allow the EUV light to be incident upon the surface of the wafer W at a predetermined angle, but the present disclosure is not limited thereto. Alternatively, the second optical system 430 may allow the EUV light to be incident perpendicularly to the surface of the wafer W.

The reticle R may be provided as a reflective mask that includes reflective and non-reflective areas. Alternatively, the reticle R may be provided as a reflective mask that includes reflective and semi-reflective areas. The reticle R may include a reflective multilayer film and an absorber layer on a base formed of a low thermal expansion coefficient material (LTEM). For example, the LTEM may be quartz. The reflective multilayer film may reflect EUV light. For example, the reflective multilayer film may have a structure where dozens or more molybdenum (Mo) films and dozens or more silicon (Si) films are alternately stacked. The absorber layer may be formed on the reflective multilayer film. The absorber layer may include a material selected from among TaN, TaNO, TaBO, Ni, Au, Ag, C, Te, Pt, Pd, and Cr. The absorber layer may correspond to the non-reflective or semi-reflective area.

The reticle R may reflect the EUV light incident through the first optical system 420 into the second optical system 430. The reticle R reflects the EUV light from the first optical system 420, structuring the EUV light according to the shape of patterns formed by the reflective multilayer film and absorber layer on the base, and directing the structured EUV light into the second optical system 430. EUV light may be structured to include secondary diffracted light based on the patterns on the reticle R. The structured EUV light may be incident upon the second optical system 430, carrying information on the shape of the patterns on the reticle R, and may be delivered through the second optical system 430 and projected onto the wafer W to form an image corresponding to the shape of the patterns. For example, the wafer W may include a semiconductor material such as Si.

The image sensor 160 may acquire an image of the surface of the reticle R. Alternatively, the image sensor 160 may acquire an image of the surface of the wafer W. The image sensor 160 may be disposed to capture an image of the surface of the reticle R or the wafer W. After acquiring an image, the image sensor 160 may provide the acquired image to the measurement position monitoring apparatus 100. The image sensor 160 may be wirelessly or wiredly connected to the measurement position monitoring apparatus 100. The image sensor 160 may also provide FOV-related information.

In response to an image being received from the image sensor 160, the measurement position monitoring apparatus 100 may extract an OS box 240a or 240b from the image and may calculate an inner center 250 of the OS box 240a or 240b. The measurement position monitoring apparatus 100 may calculate an FOV center 260 based on the FOV-related information from the image sensor 160. The measurement position monitoring apparatus 100 may compare the inner center 250 with the FOV center 260 and may calculate an error between the inner center 250 and the FOV center 260.

The measurement position monitoring apparatus 100 may adjust the position of the first stage 440. The measurement position monitoring apparatus 100 may move the first stage 440 in the first direction D1 based on the error between the inner center 250 and the FOV center 260. Alternatively, the measurement position monitoring apparatus 100 may move the first stage 440 in the second direction D2 based on the error between the inner center 250 and the FOV center 260.

The measurement position monitoring apparatus 100 may adjust the position of the reticle R on the first stage 440. The measurement position monitoring apparatus 100 may move the reticle R in the first direction D1 on the first stage 440 based on the error between the inner center 250 and the FOV center 260. Alternatively, the measurement position monitoring apparatus 100 may move the reticle R in the second direction D2 on the first stage 440 based on the error between the inner center 250 and the FOV center 260.

The measurement position monitoring apparatus 100 may adjust the position of the second stage 450. The measurement position monitoring apparatus 100 may adjust the position of the second stage 450 according to the adjusted position of the first stage 440. The measurement position monitoring apparatus 100 may move the second stage 450 in the first direction D1 or the second direction D2.

The measurement position monitoring apparatus 100 may adjust the position of the wafer W on the second stage 450. The measurement position monitoring apparatus 100 may adjust the position of the wafer W on the second stage 450 according to the adjusted position of the first stage 440. The measurement position monitoring apparatus 100 may move the wafer W on the second stage 450 in the first direction D1 or the second direction D2.

In embodiments, the semiconductor manufacturing equipment 400 may further include a substrate inspection unit 460. The substrate inspection unit 460 may measure critical dimensions (CD) or overlay errors of the patterns on the wafer W. The substrate inspection unit 460 may be provided as an optical microscope. Alternatively, the substrate inspection unit 460 may be provided as an electron microscope. For example, the substrate inspection unit 460 may be provided as a scanning electron microscopy (SEM) or transmission electron microscopy (TEM). The substrate inspection unit 460 may use a measurement method such as imaging ellipsometry (IE) or spectroscopic imaging ellipsometry (SIE). The substrate inspection unit 460 may measure CDs or overlay errors when an inspection process such as After Development Inspection (ADI) or After Cleaning Inspection (ACI) is conducted.

The image sensor 160 and the measurement position monitoring apparatus 100 may operate before the start of an exposure process. When the exposure process is yet to begin, the image sensor 160 may acquire an image, and the measurement position monitoring apparatus 100 may adjust the positions of the first stage 440 and the second stage 450, or the positions of the reticle R and the wafer W, based on the acquired image. In this manner, the apparatus 100 can prevent an incorrect transfer of patterns from the reticle R onto the wafer W and can improve the yield of semiconductors.

The image sensor 160 and the measurement position monitoring apparatus 100 may operate after the end of the exposure process. For example, the image sensor 160 and the measurement position monitoring apparatus 100 may operate when an inspection process such as ADI or ACI is conducted. The error calculation and position adjustment features of the measurement position monitoring apparatus 100 may prevent a wafer W with a transfer error from being delivered to subsequent processes. Additionally, the error calculation and position adjustment features of the measurement position monitoring apparatus 100 may prevent an incorrect transfer of patterns from the reticle R onto a wafer W to be subject to the exposure process.

The semiconductor manufacturing equipment 400 may be provided as a substrate inspection apparatus. The substrate inspection apparatus may be an apparatus capable of measuring and analyzing the characteristics of the substrate or materials formed on the substrate. The characteristics of the substrate may include thickness, concentration, optical CD (OCD), roughness, resistance, electrical properties, optical properties, chemical properties, etc. A surface or interface analysis method may be used for the analysis of the characteristics of the substrate. For example, X-ray Photoelectron Spectroscopy (XPS), Auger Electron Spectroscopy (AES), Microscope Fourier Transform Infrared Spectroscopy (Microscope FTIR), X-ray Diffraction Spectroscopy (XRD), X-ray Fluorescence (XRF), Scanning Electron Microscopy (SEM), Transmission Electron Microscopy (TEM), Electron Probe Microanalysis (EPMA), or Scanning Probe Microscopy (SPM) may be used.

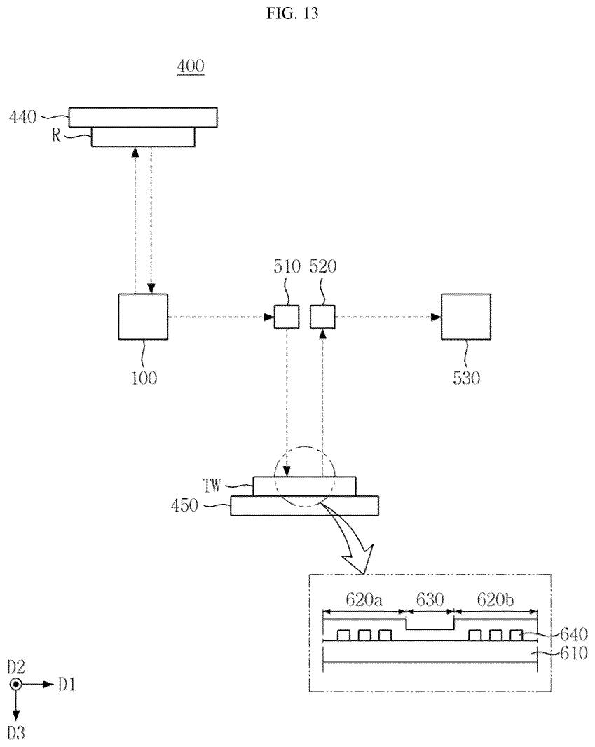

For example, the semiconductor manufacturing equipment 400 may be provided as an apparatus for measuring the thickness of thin films (e.g., oxide films) formed on the surface of the substrate. The semiconductor manufacturing equipment 400 may measure the thickness of oxide films in a non-destructive manner. FIG. 13 is a third exemplary diagram for explaining the semiconductor manufacturing equipment including the measurement position monitoring apparatus according to some embodiments of the present disclosure.

Referring to FIG. 13, the semiconductor manufacturing equipment 400 may be configured to include a light-emitting unit 510, a light-receiving unit 520, a thickness calculation unit 530, and a measurement position monitoring apparatus 100. The measurement position monitoring apparatus 100 may include a pattern extractor 110, a calculator 120, a comparator 130, a position error calculator 140, a controller 150, and an image sensor 160.

The light-emitting unit 510 may apply light to a target object TW. The light-emitting unit 510 may apply light to an OS within the target object TW. The target object TW may be a wafer.

Chip pattern areas 620a and 620b and an OS 630 may be provided on a base 610 of the target object TW. The chip pattern areas 620a and 620b may include chip patterns 640, which are formed on the base 610. The chip patterns 640 may contain information on each of first, second, third, and fourth cells 230a, 230b, 230c, and 230d in a reticle R. The OS 630 may be disposed between two different chip pattern areas 620a and 620b. The position of the OS 630 may correspond to the position of a scribe lane within the target object TW. OS boxes within the scribe lane may be positioned within the OS 630.

The light-receiving unit 520 may receive light reflected from the target object TW. The light-receiving unit 520 may provide information acquired from the received reflected light to the thickness calculation unit 530.

The thickness calculation unit 530 may calculate the thickness within the OS 630 based on information received from the light-receiving unit 520. The thickness calculation unit 530 may be provided as a computing device. The thickness calculation unit 530 may be provided as a separate computing device from the measurement position monitoring apparatus 100, but the present disclosure is not limited thereto. Alternatively, the thickness calculation unit 530 and the measurement position monitoring apparatus 100 may be integrated into a single computing device.

In embodiments, the semiconductor manufacturing equipment 400 may further include a camera sensor and a luminance measurement unit. The camera sensor may receive reflected light and may provide an image signal obtained from the reflected light to the luminance measurement unit. The luminance measurement unit may measure luminance based on information provided by the camera sensor and may provide the measured luminance to the thickness calculation unit 530. The luminance measurement unit may differentiate light by color and may provide a luminance value measured from a specific color of light to the thickness calculation unit 530.

The measurement position monitoring apparatus 100 may capture an image of the surface of a substrate 220, may extract an OS box 240a or 240b from the image, and may calculate an inner center 250 of the OS box 240a or 240b. The measurement position monitoring apparatus 100 may calculate an FOV center 260 based on FOV information associated with the image. The measurement position monitoring apparatus 100 may compare the inner center 250 and the FOV center 260 and may calculate an error between the inner center 250 and the FOV center 260.

A wafer W may be provided in the same size as the reticle R. The controller 150 may estimate the position of the OS 630 within the wafer W based on the position of a scribe lane 210a or 210b in the reticle R. The controller 150 may estimate a point corresponding to the position of the OS box 240a or 240b within the OS 630. The controller 150 may adjust the point within the OS 630 that corresponds to the position of the OS box 240a or 240b based on the error between the inner center 250 and the FOV center 260. The controller 150 may provide the adjusted point to the light-emitting unit 510. The light-emitting unit 510 may apply light to the adjusted point.

Meanwhile, as semiconductor processes become more refined, the size of OS boxes diminishes, leading to increased measurement errors as optical beams may deviate the OS boxes due to stage and pattern alignment inaccuracies. This emphasizes the importance of monitoring the error between the center of an OS box and its corresponding measurement position, especially given the lack of measurement margin between the size of an optical beam and the size of the OS box.

The measurement position monitoring apparatus 100 can quantify errors through position-based analysis using images and can monitor shifts and misalignments in measurement points. Using deep learning, the measurement position monitoring apparatus 100 can calculate the center of each measurement point's box area and compare the calculated center with the actual measurement to assess accuracy and alignment errors. The measurement position monitoring apparatus 100 can prevent errors during the quality inspection of each substrate through error compensation. The measurement position monitoring apparatus 100 can detect potential equipment anomalies in advance by detecting any deviations at any measurement point, enabling the implementation of preemptive measures through the evaluation of stage accuracy and the calibration of stage mapping.

At least one of the components, elements, modules and units (collectively “components” in this paragraph) represented by a block in the drawings such as FIGS. 1, 9 and 10 may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU), a microprocessor, or the like that performs the respective functions.

Embodiments of the present disclosure have been described above with reference to the accompanying drawings, but the present disclosure is not limited thereto and may be implemented in various different forms. It will be understood that the present disclosure can be implemented in other specific forms without changing the technical concept or gist of the present disclosure. Therefore, it should be understood that the embodiments set forth herein are illustrative in all respects and not limiting.

What is claimed is:

1. A measurement position monitoring apparatus, the measurement position monitoring apparatus comprising:
a pattern extractor extracting a pattern from an image associated with a substrate, wherein the pattern is a bounded pattern;
a calculator calculating a position of a target point within the extracted pattern;
a comparer comparing the target point with a reference point; and
a position error calculator calculating a position error in the target point.

2. The measurement position monitoring apparatus of claim 1, wherein the position error includes a first component in a first direction and a second component in a second direction that is perpendicular to the first direction.

3. The measurement position monitoring apparatus of claim 1, wherein the position error calculator calculates the position error based on a distance between the target point and the reference point.

4. The measurement position monitoring apparatus of claim 3, wherein the position error calculator converts pixels within the image into distance values.

5. The measurement position monitoring apparatus of claim 1, wherein the extracted pattern is formed within a scribe lane between a plurality of cells.

6. The measurement position monitoring apparatus of claim 5, wherein the extracted pattern is associated with an oxide site (OS) box.

7. The measurement position monitoring apparatus of claim 1, wherein the target point is an inner center of the extracted pattern.

8. The measurement position monitoring apparatus of claim 1, wherein the reference point is associated with image sensor that has acquired the image.

9. The measurement position monitoring apparatus of claim 8, wherein the reference point is associated with a center of a field of view (FOV) of the image sensor.

10. The measurement position monitoring apparatus of claim 1, wherein the position error calculator calculates the position error based on a number of pixels between the target point and the reference point.

11. The measurement position monitoring apparatus of claim 1, further comprising:
a control unit controlling a control position of a control target based on the position error.

12. The measurement position monitoring apparatus of claim 11, wherein the control unit adjusts a stage position of a stage supporting the substrate.

13. The measurement position monitoring apparatus of claim 1, wherein the measurement position monitoring apparatus is used when inspecting patterns or materials on the substrate.

14. The measurement position monitoring apparatus of claim 1, wherein the measurement position monitoring apparatus is used when comparing patterns between a reticle and the substrate.

15. Semiconductor manufacturing equipment comprising:
a stage supporting a substrate;
a substrate inspection unit inspecting the substrate; and
a measurement position monitoring apparatus monitoring a position of a target point within the substrate,
wherein the measurement position monitoring apparatus comprises:
a memory storing one or more instructions; and
at least one processor configured to execute the one or more instructions,
wherein the one or more instructions, when executed by the at least one processor, cause the measurement position monitoring apparatus to:
extract a pattern from an image associated with the substrate, wherein the pattern is a bounded pattern,
calculate the position of the target point within the extracted pattern,
compare the target point with a reference point, and
calculate a position error in the target point.

16. The semiconductor manufacturing equipment of claim 15, wherein the one or more instructions, when executed by the at least one processor, further cause the measurement position monitoring apparatus to control a control position of the stage based on the position error.

17. The semiconductor manufacturing equipment of claim 15, further comprising:
a light source generating and outputting light;
a first stage supporting a reticle;
a second stage supporting the substrate;
a first optical system reflecting light from the light source to be incident upon a surface of the reticle; and
a second optical system reflecting light passing through the reticle to be incident upon a surface of the substrate.

18. The semiconductor manufacturing equipment of claim 15, wherein the substrate inspection unit measures a thickness of an oxide film formed between patterns in the substrate.

19. The semiconductor manufacturing equipment of claim 18, further comprising:
a light-emitting unit applying light in a direction where the substrate is positioned;
a light-receiving unit receiving light reflected from the substrate; and
a thickness calculation unit calculating the thickness of the oxide film using the received light by the light-receiving unit.

20. A method for monitoring measurement position, the method being executed by at least one processor, the method comprising:
extracting a pattern from an image associated with a substrate, wherein the pattern is a bounded pattern;
calculating a position of a target point within the extracted pattern;
comparing the target point with a reference point; and
calculating a position error in the target point,
wherein
the extracted pattern is formed within a scribe lane between a plurality of cells and is associated with an oxide site (OS) box,
the target point is the target point is an inner center of the extracted pattern,
the reference point is associated with a field of view (FOV) of an image acquisition unit that has acquired the image,
the position error includes a first component in a first direction and a second component in a second direction that is perpendicular to the first direction, and
calculating the position error comprises calculating a distance between the target point and the reference point based on pixels within the image and calculates the position error based on the distance.
